(19) United States
(12) Patent Application Publication
(10) Pub. No.: US 2009/0166866 A1
(43) Pub. Date: Jul. 2, 2009

(54) CONTACT METALLIZATION FOR SEMICONDUCTOR DEVICES

(76) Inventors: Michal Efrati Fastow, Cupertino, CA (US); Michelle Rincon, San Francisco, CA (US); Max Wei, Albany, CA (US)

Correspondence Address: INTEL CORPORATION;c/o CPA Global, P.O. BOX 52050, MINNEAPOLIS, MN, 55402, US

(21) Appl. No.: 11/968,134

(22) Filed: Dec. 31, 2007

(51) Int. Cl. H01L 23/52; H01L 21/4763

(52) U.S. Cl. 257/751; 438/643; 257/E23.141; 257/E21.495

(57) ABSTRACT

Methods for forming metal contacts to silicon substrates in semiconductor devices for contact diameters less than 60 nm and the devices formed from such processes are described. The methods includes the steps of pre-cleaning the silicon surface where the metal contact will be formed, depositing a silicide material and a sacrificial liner, forming the silicide material, removing or stripping the non-reacted portions of the silicide material non-reacted portions of the sacrificial liner, optionally performing an additional oxide clean, and depositing the liner and the metal for the contact. Such a process allows the formation of W contacts with dimension of 60 nm and below without a significant amount of defects.

### FIELD

The application generally relates to integrated circuits (ICs) or semiconductor devices and methods for making such devices. More particularly, this application relates to forming metal contacts to silicon substrates in semiconductor processing for contact diameters less than 60 nm.

### BACKGROUND

Semiconductor devices are built in semiconductor materials, typically silicon wafers (or substrates), through a series of processes. One of these processes forms a contact between a conductive layer (usually containing a metal) and the silicon in the substrate. The metal layers (or lines) are necessary to connect the various devices together on the substrate. The interface between the metal layer and the silicon is often referred to as a metal contact.

### BRIEF DESCRIPTION OF THE DRAWINGS

The following description can be better understood in light of the Figures, in which:

FIG. 1A illustrates a cross section view of a exemplary semiconductor device after a pre-cleaning has removed oxide on the silicon;

FIG. 1B contains a transmission electron microscope (TEM) of the structure illustrated in FIG. 1A;

FIG. 2A illustrate a cross section view of a exemplary semiconductor device after depositing a silicide material (or sacrificial liner);

FIG. 2B contains TEM of the structure illustrated in FIG. 2A;

FIG. 3A illustrates a cross section view of a exemplary semiconductor device after silicide formation;

FIG. 3B contains a TEM of the structure illustrated in FIG. 3A;

FIG. 4A illustrates a cross section view of a exemplary semiconductor device after removing (or stripping) the non-reacted silicide material;

FIG. 4B contains a top view TEM of the structure illustrated in FIG. 4A prior to removing (or stripping) the non reacted silicide material;

FIG. 4C contains a top view TEM of the structure illustrated in FIG. 4A after removing (or stripping) the non reacted silicide material;

FIG. 5 illustrates a cross section view of a exemplary semiconductor device after depositing a contact layer (or liner deposition);

FIG. 6A illustrates a cross section view of a exemplary semiconductor device after the metal (W) fill;

FIG. 6B contains a top view TEM of the structure illustrated in FIG. 6A;

FIG. 7 contains TEM of an exemplary 35 nm metalized contact with silicon substrate; and

FIG. 8 contains a TEM of exemplary 35 nm multiple metalized contacts.

The Figures illustrate specific aspects of the semiconductor devices and associated methods of making and using such devices. Together with the following description, the Figures demonstrate and explain the principles of the semiconductor devices and associated methods. In the drawings, the thickness of layers and regions are exaggerated for clarity. It will also be understood that when a layer is referred to as being “on” another layer or substrate, it can be directly on the other layer or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor devices and methods for making and using such device can be implemented and used without employing these specific details. For example, while the description focuses on semiconductor devices, it can be modified to be used in other electrical devices that are formed using similar methods. Although the description below focuses on contact metallization between a silicon substrate and tungsten metal lines, this process can be applied to other areas on a semiconductor and using other metals to achieve similar advantages and results.

To be profitable and stay competitive, semiconductor manufacturers are continuously reducing or shrinking the size of semiconductor devices so they can produce more devices for every wafer used. But in some instances, this shrinkage process can create defects in smaller devices when they are shrunk and the component of the semiconductor devices are squeezed closer together. For example, current processes (that operate at dimensions >60 nm) do not provide for low-resistance contact metallization between Tungsten (W) and Silicon (Si). Low resistance between the silicon and the metal are necessary to reduce the power consumption and reduce the heat created since heat in semiconductor devices degrades speed and performance. But current processes do not allow W to form metal contacts with diameters less than 60 nm without resulting in an unacceptable level of defects.

The process for contact metallization contains a series of steps enabling low ohmic contact between the silicon in the source or drain regions and metal lines. The source and drain are two parts of a transistor separated by a gate, the third part of that transistor. The source and drain regions are created by diffusing elements like boron (B), phosphorous (P), arsenic (As) in silicon to change the silicon's electrical properties. Contact metallization is a sequence of deposition, thermal treatments, wet cleans and wet etches (or strip) that forms a low resistance contact to silicon (Si).

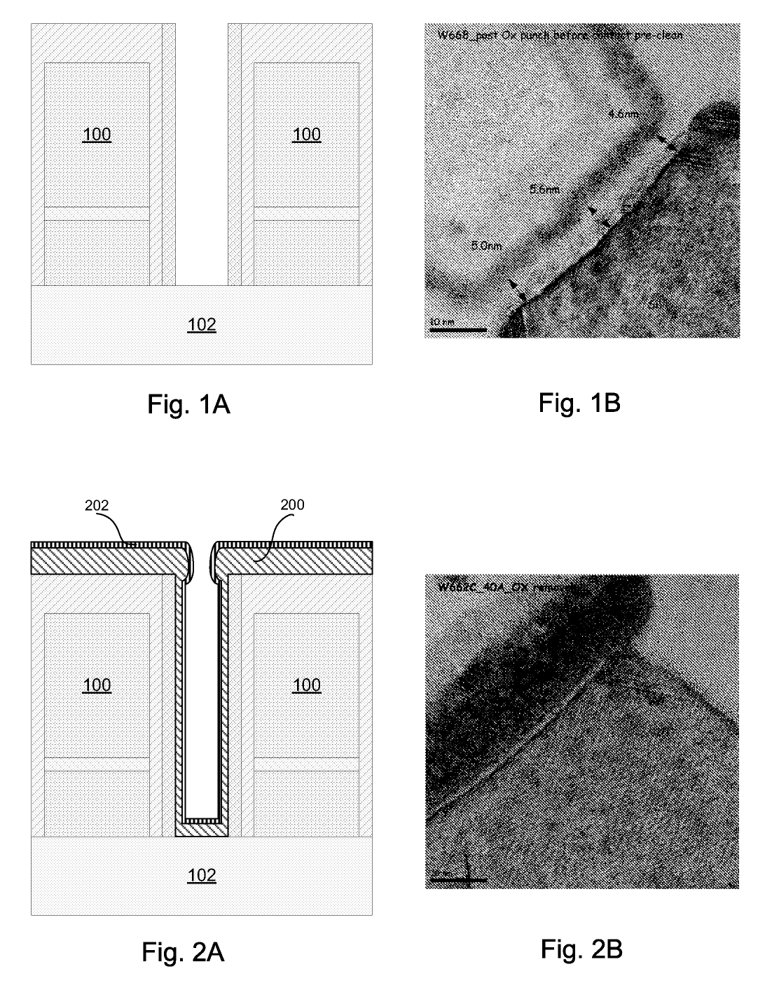

The contact metallization process begins with an etching process, or pre-clean, as shown in FIGS. 1A and 1B. Using a wet clean process, the contact area is cleansed of oxide or contamination left after a patterning has been used to expose the silicon substrate 102. Although a wet clean can be used to perform the pre-clean, any process that cleans oxide or contamination can also be used. Oxide (or silicon oxide) is an insulator, so it creates high resistance. An example of an existing oxide structure 100 (used to protect and insulate the silicon substrate 100) that contains narrow trench is illustrated in FIG. 1A. The pre-clean is advantageous so a low resistance or low ohmic contact forms between the silicon and later added silicide material. A low resistance contact will decrease the heat generated from resistance when current runs through the contact. The low resistance contact will also reduce the power consumption due to heat loss at the contact.

Next, a contact metal deposition deposits a layer of metal. An example of this metal deposition is illustrated in FIGS. 2A and 2B. The contact metal or conductive layer 200 can be titanium (Ti), cobalt (Co), nickel (Ni), or other metals capable of reacting with silicon 102 to form a silicide alloy. The contact metal can be deposited using any conventional deposition method, like chemical vapor deposition (CVD) and sputtering. This contact metal will later be reacted with the silicon using heat and be absorbed into the silicon to form thin low resistance silicide (which is a silicon and metal alloy).

Next, a liner deposition step deposits a protective layer on the contact metal to impede oxidation growth during the silicide formation. An example of this process is illustrated in FIGS. 2A and 2B. This protective layer or sacrificial liner 202 can be titanium nitride (TiN), tungsten nitride (WN), or other compounds providing a protective layer to the contact metal 200. The sacrificial liner can be deposited using any conventional deposition method. The liner is deposited to protect the contact metal from oxidation during the silicide formation (which requires an anneal process with heat). The heat used to form silicide can also cause the contact metal to oxidize and impair proper salicide formation. So the protective layer retards the oxidation process.

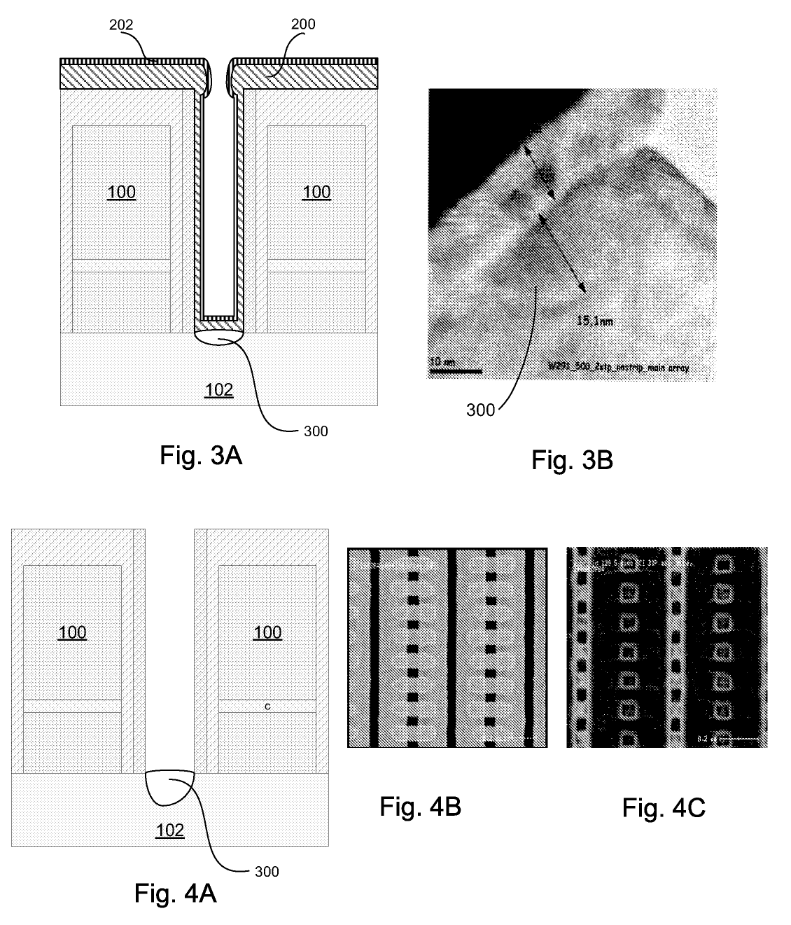

Next, a silicide formation step uses a rapid thermal anneal process to melt the contact metal into the silicon in the contact region and form a silicide. An example is illustrated in FIGS. 3A and 3B. The rapid thermal anneal process heats the silicon surface to a high temperature for a short period of time to create a metal silicide 300 which forms a low ohmic contact between the metal and the silicon 102. The silicide 300 forms a contact that will later bond with tungsten metal lines and plugs that will be formed later in the process. Although rapid thermal anneal process can be used to form the silicide, any thermal method that forms silicide can also be used.

Next, a strip process is used to remove the remaining non-reacted metal and sacrificial liner from the top of the contact area and the sidewalls. An example of this process is illustrated in FIGS. 4A, 4B (showing a TEM view before the strip process), and 4C (showing a TEM view after the strip process). The strip process comprises a wet etch which removes the metal and sacrificial liner remaining on the surface of the silicon contact and sidewalls after the silicide formation step. This process leaves only the reacted silicide 300 in the silicon substrate 102. The strip process helps tungsten (W) or another metal to fill in the small dimensions and narrow trench (including a pin hole) and plug openings because it removes excess material from the trenches, allowing more metal to fill the contact and form a better metal contact. Although a wet etch can be used to remove the non-reacted metal and sacrificial liner, any method that removes the non-reacted metal and sacrificial liner can also be used.

Next, a pre-adhesion clean follows the strip process and can be used to remove any oxide acting as high resistance layer between the silicide and the later-deposited tungsten (W) metal in the contact region. An example of this process is illustrated in FIG. 4A. Silicon oxide, also known as oxide, grows during various processing steps and creates an insulation layer and greater electrical resistance. Removing or etching this oxide from the silicon substrate 102 helps to create low resistance contacts and eliminate heat dissipated through the contact. Although the pre-adhesion clean can utilize either wet or dry etches, any cleaning method that removes oxide can also be used.

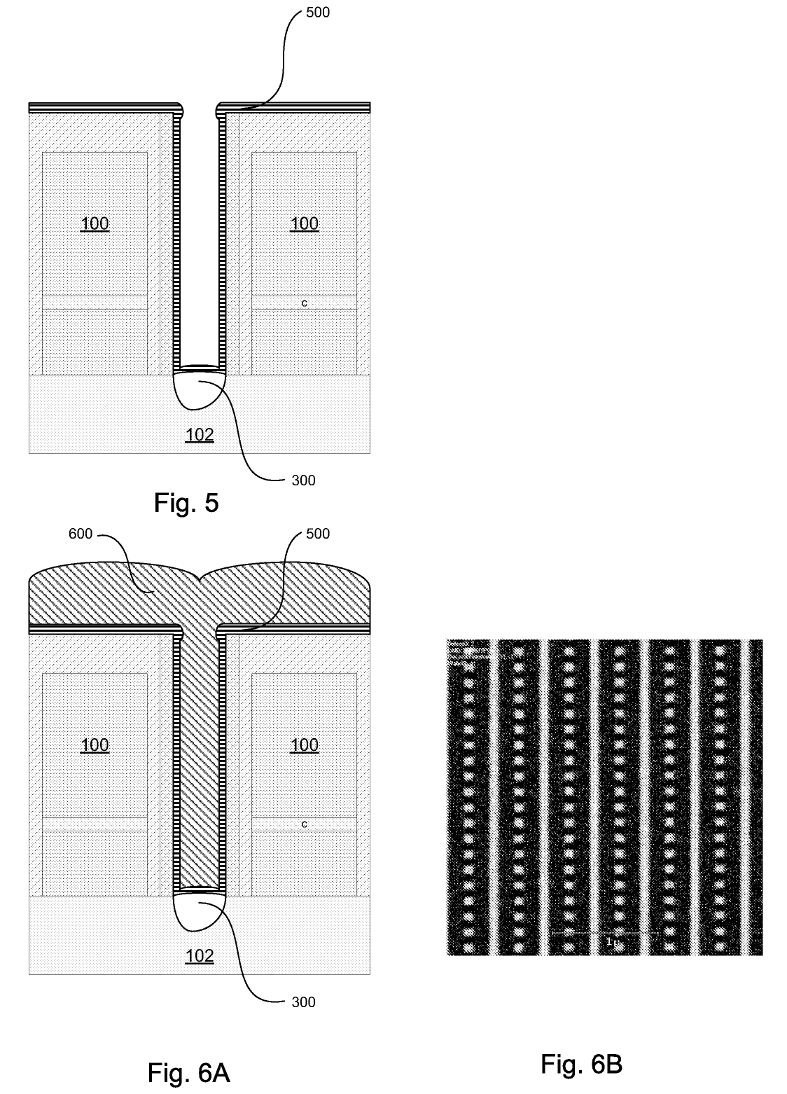

Next, an adhesion deposition process is used to deposit a thin conducting layer to create an adhesion between the tungsten (to be deposited later) and the silicon. An example of this process is illustrated in FIG. 5. The adhesion deposition 500 not only creates good adhesion between the later applied tungsten and the contact area on the silicon substrate 102, but also creates good adhesion to the other supporting structures surrounding the contact area (like the sidewalls). This allows the tungsten metal to attach to the sidewalls and be supported by more than just the contact area. The conducting layer of the adhesion layer 500 can be deposited using any conventional deposition method known in the art.

Finally, a metal deposition process deposits the metal for the conducting layer 600. While any metal can be used in conducting layer 600, in some embodiments W is used as the metal. The deposited conducting layer adheres to the silicon and forms a low resistance contact with the silicide 300 in the silicon substrate 102. An example of this process is illustrated in FIGS. 6A and 6B. The tungsten layer 600 is patterned to form various metal lines which electrically connect the various portions of the semiconductor device together. This low resistance contact consumes low amounts of power and generates low amounts of heat. The tungsten can be deposited using any conventional deposition method, like CVD and sputtering, but any metal deposition method can be used.

An advantage of this process outlined above is to form a silicide after the contact openings are formed, instead of forming the silicide regions earlier in the process. This later formation of silicide allows higher temperatures to be used in the processing. Heat and high temperatures have an adverse effect on silicide since higher temperatures cause the metal in the silicide alloy to meld, expand, agglomerate, diffuse, and migrate in the silicon so the area of the silicide extends both deeper and wider in the silicon substrate. This silicide expansion can both dilute the concentration of the silicide, creating a higher resistance in the contact area and extending into other unintended parts of the device impairing or destroying device performance. Moving the silicide formation into a later part of the process flow keeps the silicide formation narrow and concentrated in the predetermined region, enabling devices to shrink down to dimensions of 30 nm while still allowing thermal steps to be used earlier in the flow.

The strip step or removal of the non-reacted silicide material and sacrificial liner provides another advantage because it creates a larger opening in the trench for the tungsten (W) to fill. Because the heat used in the silicide formation causes the remaining non-reacted metal or silicide material to oxidize, this metal is more resistive than the pure tungsten used to fill the contact trenches. The more resistive oxide material generates more heat than the pure metal when current runs through it, and heat degrades performance in semiconductors. Both of these advantages allow for smaller metal contacts in next generation die shrinks.

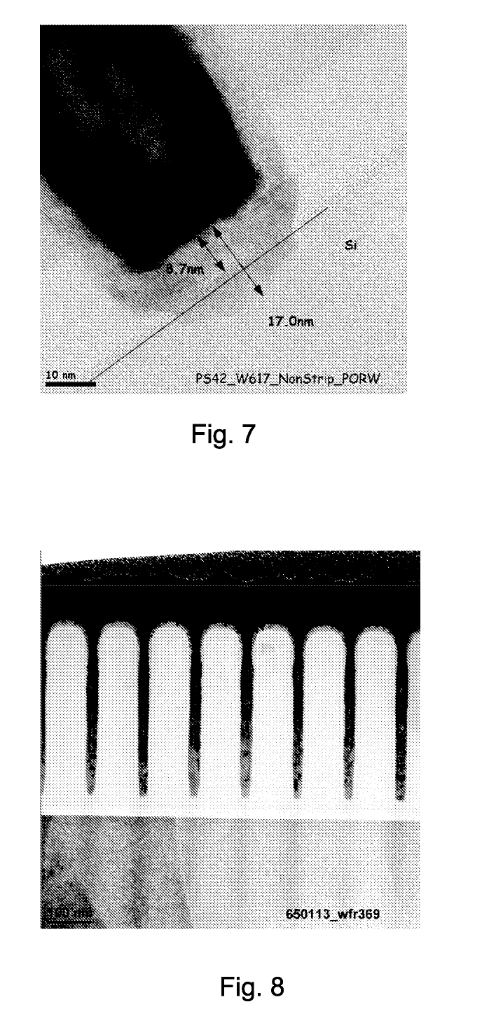

The process outlined above manufactures metal contacts and structures with several advantageous features. The process allows formation of metal contacts with a radius of about 60 nm or less, and in some embodiments, about 45 nm or less. One structure formed from this process comprises pin-shaped metal contacts with a radius of 35 nm or less, as shown in FIGS. 7 and 8. The tips of these metal contacts have a low ohmic resistance that forming the contact area with a source or drain region of a transistor. As shown in FIGS. 7 and 8, a conducting layer exists on the surface of the pin shaped contacts, which adheres to both the oxide sidewalls and the silicide in the silicon substrate. And no silicide residue more than 50 angstroms exists between the W conducting layer and oxide sidewalls (or silicide in the silicon substrate).

Having described the preferred aspects of the devices and associated methods, it is understood that the appended claims are not to be limited by particular details set forth in the above description, as many apparent variations thereof are possible without departing from the spirit or scope thereof.

1. A method for forming a metal contact in a semiconductor device, comprising:
providing a silicon substrate with an oxide layer containing a trench with a sidewall;
depositing a first metal layer on the surface of the substrate;
depositing a metal liner on the surface of the first metal;
forming a silicide by heating the first metal and the silicon;
removing an unreacted portion of the first metal that has not formed a silicide;
depositing a conducting layer on the sidewall of the trench and the surface of the substrate; and
depositing a second metal layer on the conducting layer.

2. The method of claim 1, further comprising removing any oxide off the surface of the silicon substrate prior to depositing the first metal.

3. The method of claim 2, wherein the removal of the oxide comprises a wet clean process.

4. The method of claim 1, wherein the first metal comprises titanium, cobalt, or nickel.

5. The method of claim 1, wherein the liner material comprises titanium nitride or tungsten nitride.

6. The method of claim 1, wherein heating the first metal and the substrate uses a rapid thermal anneal process.

7. The method of claim 1, wherein the removal of the non-reacted first metal comprises a wet etch process.

8. The method of claim 1, further comprising removing any oxide that has formed on the silicon during the heating process that forms the silicide.

9. The method of claim 1, wherein the second metal comprises tungsten.

10. The method of claim 1, wherein the width of the trench is about 60 nm or less.

11. A metal contact for a semiconductor device formed by the method comprising:
providing a silicon substrate with an oxide layer containing a trench with a sidewall;
depositing a first metal layer on the surface of the substrate;
depositing a metal liner on the surface of the first metal;
forming a silicide by heating the first metal and the silicon;
removing an unreacted portion of the first metal that has not formed a silicide;
depositing a conducting layer on the sidewall of the trench and the surface of the substrate; and
depositing a second metal layer on the conducting layer.

12. The metal contact of claim 11, wherein the method further comprises removing any oxide off the surface of the silicon substrate prior to depositing the first metal.

13. The metal contact of claim 11, wherein the method further comprises removing any oxide that has formed on the silicon during the heating process that forms the silicide.

14. The metal contact of claim 11, wherein the second metal comprises tungsten.

15. The metal contact of claim 11, wherein the width of the trench is about 60 nm or less.
